(19) United States
(12) Patent Application Publication
(10) Pub. No.: US 2015/0372216 A1
(43) Pub. Date: Dec. 24, 2015

(54) Thermodiode Element for a Photosensor for Infrared Radiation Measurement, Photosensor and Method for producing a Thermodiode Element

(71) Applicant: Robert Bosch GmbH, Stuttgart (DE)

(72) Inventors: Christoph Schelling, Stuttgart (DE); Fabian Utermoehlen, Stuttgart (DE); Ingo Herrmann, Friolzheim (DE)

(21) Appl. No.: 14/744,664

(22) Filed: Jun. 19, 2015

(30) Foreign Application Priority Data
Jun. 20, 2014 (DE) 10 2014 211 829.8

(51) Int. Cl. H01L 37/02; H01L 31/0224; H01L 31/18; H01L 31/09

(52) U.S. Cl. CPC H01L 37/02; H01L 31/09; H01L 31/0224; H01L 31/18

(57) ABSTRACT

A thermodiode element for a photosensor of a thermocamera usable for infrared radiation measurement includes a semiconductor substrate that has a first layer, and a second layer adjoining the first layer. The first layer has a base doping zone, and the second layer has a side doping zone that is the same doping type as the base doping zone. The second layer also has a further doping zone that is arranged as an island in the side doping zone and that has a doping type that is opposite to the doping type of the base doping zone. The base doping zone is further arranged in the first layer so as to adjoin the further doping zone.

This application claims priority under 35 U.S.C. §119 to patent application no. DE 10 2014 211 829.8, filed on Jun. 20, 2014 in Germany, the disclosure of which is incorporated herein by reference in its entirety.

The present disclosure relates to a thermodiode element for a photosensor for a thermocamera for infrared radiation measurement, to a photosensor for a thermocamera for infrared radiation measurement, and to a method for producing a thermodiode element for a photosensor for a thermocamera for infrared radiation measurement.

### BACKGROUND

Thermographic cameras for spatially resolved temperature measurement use a thermally sensitive sensor arrangement in which an inherent thermal radiation of an object is imaged onto an arrangement of thermosensitive sensor elements Infrared radiation heats the sensor elements by amounts of the order of magnitude of a few millikelvins. Conventional pixel designs require an all-round passivation of the thermosensitive element, which is costly to produce.

### SUMMARY

Against this background, the approach presented here presents an improved thermodiode element for a photosensor for a thermocamera for infrared radiation measurement, furthermore an improved photosensor for a thermocamera for infrared radiation measurement and, finally, a corresponding method for producing a thermodiode element for a photosensor for a thermocamera for infrared radiation measurement.

Advantageous embodiments are evident from the claims, the drawings, and the following description.

A low-noise thermodiode element can be produced from a semiconductor substrate having at least two different doped regions. In this case, in a well of a first doping type, there is arranged a further doping zone of a doping type opposite to the first doping type. In this case, the region designated here as a well can comprise, in particular in terms of fabrication technology, two doping zones.

A thermodiode element for a photosensor for a thermocamera for infrared radiation measurement is presented, wherein the thermodiode element comprises the following features:

a semiconductor substrate having a first layer and a second layer adjoining the first layer;

a base doping zone in the first layer, wherein the base doping zone has a first doping type;

a side doping zone in the second layer, wherein the side doping zone has the first doping type; and

a further doping zone in the second layer as an island in the side doping zone, wherein the base doping zone is arranged in a manner adjoining the further doping zone, and wherein the further doping zone has a second doping type, which is opposite to the first doping type.

A thermodiode element can be understood to mean a sensor element or a thermodiode. The thermodiode element can also be designated as a silicon island. The thermodiode element can be a microelectronic component. The thermodiode element can be used for detecting infrared rays. In this case, for example long-wave infrared radiation can be detected, for example wavelengths in the range of approximately 8 to 14 μm. The semiconductor substrate can be designated as a wafer. The first layer and additionally or alternatively the second layer of the semiconductor substrate can be formed as monocrystalline layers. A doping zone can be understood to mean a region of the semiconductor substrate which has a specific doping. The base doping zone can fill or comprise the first layer. The base doping zone can extend over a layer thickness of the first layer. The second layer can comprise the side doping zone and the further doping zone. The side doping zone and the further doping zone can in each case extend over a layer thickness of the second layer. The further doping zone can be encompassed or enclosed by the side doping zone. In this case, the base doping zone can be arranged adjacent to the side doping zone and to the further doping zone. The base doping zone and the side doping zone can together form a well enclosing the further doping zone apart from one side. In this regard, either the base doping zone or the side doping zone can adjoin the further doping zone in five spatial directions. The first doping type can denote a p-type doping and the second doping type can denote an n-type doping. Alternatively, the first doping type can denote an n-type doping and the second doping type can denote a p-type doping. In the case of an n-type doping, a freely mobile negative charge can be introduced. In the case of a p-type doping, a freely mobile positive gap, also called hole or defect electron, can be introduced. A low-noise, high-sensitivity thermodiode element for thermographic applications, based on the bolometric principle, is advantageously provided.

The base doping zone and additionally or alternatively the side doping zone can have a high doping. Different degrees of doping can be differentiated as high doping (n+; p+), medium doping (n; p) and weak doping (n−, p−). A p-n junction having a space charge zone can be formed, for example, by spatially adjacent different doping regions or doping zones in the semiconductor substrate. The high doping can represent for example a degree of doping of more than 10¹⁸ defects or doping atoms per cm³.

The further doping zone can have a medium doping. In particular, a medium doping can represent a degree of doping in a range of between 10¹⁵ defects per cm³ and 10¹⁸ defects per cm³.

It is also expedient if the thermodiode element comprises a contact doping zone, which is embedded as a contacting area for an external contact of the thermodiode element within the further doping zone. The contact doping zone can have the second doping type. The contact doping zone can have a higher doping than the further doping zone.

In one embodiment, the contact doping zone can have a high doping.

The contact doping zone can be arranged at a surface at a constant distance from the side doping zone in a tolerance range. In this regard, the further doping zone can have a constant thickness in a tolerance range between the contact doping zone and the side doping zone. The further doping zone can have the same constant thickness between the base doping zone and the contact doping zone as between the contact doping zone and the side doping zone in a tolerance range. The tolerance range can comprise 10 percent in one embodiment.

The thermodiode element can comprise a first contact and a second contact. The first contact can be arranged at the side doping zone and the second contact can be arranged at the further doping zone or alternatively at the contact doping zone. A contact can be formed for example as a contact pad, as a line or as a metallic lead.

The first layer and the second layer together can have a layer thickness of a maximum of four micrometers. In this case, the layer thickness of the first layer can be designed to be smaller than the layer thickness of the second layer. The layer thickness of the second layer can be at least three times the layer thickness of the first layer.

A photosensor for a thermocamera for infrared radiation measurement is presented, wherein the photosensor comprises an array having a plurality of thermodiode elements according to any of the preceding embodiments.

A method for producing a thermodiode element for a photosensor for a thermocamera for infrared radiation measurement is presented, wherein the method comprises the following steps:

providing a semiconductor substrate;

forming a layer construction having a first layer and a second layer on the semiconductor substrate, wherein a base doping zone having a first doping type is formed in the first layer and a side doping zone having the first doping type and a further doping zone having a second doping type, which is opposite to the first doping type, are formed in the second layer by means of a method of semiconductor technology, wherein the further doping zone is formed as an island in the side doping zone and the base doping zone is formed in a manner adjoining the further doping zone.

In the method for producing a thermodiode element, the step of forming can comprise a step of creating the first layer as a monocrystalline layer on the semiconductor substrate, wherein the first layer has the base doping zone, a step of applying the second layer as a monocrystalline layer on the first layer, wherein the second layer has the further doping zone, and a step of introducing a dopant of the first doping type into a region of the second layer which surrounds the further doping zone, in order to form the side doping zone. The thermodiode element can be constructed in a layered fashion in this way.

The method for producing a thermodiode element can comprise a further step of introducing a dopant of the second doping type into the further doping zone. A contact doping zone can advantageously be formed as a result.

The method for producing a thermodiode element can comprise a step of arranging a first contact at the side doping zone and a second contact at the further doping zone or the contact doping zone. The first contact and the second contact can be formed as contact pad or as metallic leads. The thermodiode element can be electrically contacted via the contacts.

The method for producing a thermodiode element can comprise a step of exposing, in which at least the base doping zone, the side doping zone and the further doping zone of the thermodiode element are exposed. By way of example, the step of exposing can advantageously be implemented by means of an etching process. A silicon island comprising the base doping zone, the side doping zone and the further doping zone can be exposed in the step of exposing.

### BRIEF DESCRIPTION OF THE DRAWINGS

The approach presented here is explained in greater detail by way of example below with reference to the accompanying drawings, in which:

FIG. 1 shows a schematic illustration of a thermodiode element for a photosensor for a thermocamera for infrared radiation measurement in accordance with one exemplary embodiment of the present disclosure;

FIG. 2 shows a sectional view of a thermodiode element in accordance with one exemplary embodiment of the present disclosure;

FIG. 3 shows a sectional view of a thermodiode element in accordance with one exemplary embodiment of the present disclosure;

FIG. 4 shows a sectional view of a thermodiode element in accordance with one exemplary embodiment of the present disclosure;

FIG. 5 shows a sectional view of a thermodiode element in accordance with one exemplary embodiment of the present disclosure;

FIG. 6 shows a schematic illustration of a thermocamera comprising a photosensor in accordance with one exemplary embodiment of the present disclosure;

FIG. 7 shows a flow chart of a method for producing a thermodiode element for a photosensor in accordance with one exemplary embodiment of the present disclosure; and

FIG. 8 shows a flow chart of a method for producing a thermodiode element in accordance with one exemplary embodiment of the present disclosure.

### DETAILED DESCRIPTION

In the following description of expedient exemplary embodiments of the present disclosure, identical or similar reference signs are used for the elements having a similar effect that are illustrated in the various figures, a repeated description of these elements being dispensed with.

FIG. 1 shows a schematic illustration of a thermodiode element 100 for a photosensor for a thermocamera for infrared radiation measurement in accordance with one exemplary embodiment of the present disclosure. The thermodiode element 100 comprises a semiconductor substrate having a first layer 102 and a second layer 104 adjoining the first layer.

The first layer 102 comprises a base doping zone 106. The second layer 104 comprises a side doping zone 108 and a further doping zone 110. The base doping zone 106 and the side doping zone 108 together form a well for the further doping zone 110. In this regard, the side doping zone 108 directly adjoins the base doping zone 106 at one side. The further doping zone 110 is completely encompassed by the side doping zone 108. It is not directly apparent in FIG. 1 that the further doping zone 110 directly adjoins the base doping zone 106. This becomes visible in the subsequent figures illustrating exemplary embodiments as a sectional view along the sectional plane identified by A-A.

The base doping zone 106 and the side doping zone 108 have the same first doping type. Depending on the exemplary embodiment, the first doping type is a p-type doping or alternatively an n-type doping. The further doping zone 110 has a second doping type which is opposite to the first doping type. In this regard, the further doping zone 110 has an n-type doping if the first doping type comprises a p-type doping, or alternatively the further doping zone 110 has a p-type doping if the base doping zone 106 and the side doping zone 108 have an n-type doping.

In the exemplary embodiment shown in FIG. 1, a contour of the further doping zone 110 in a plan view at the surface 112 of the thermodiode element 100 has the shape of a rectangle. In this case, surface 112 denotes that side of the second layer 104 which faces away from the base doping zone 106. In this regard, said contour can have the shape of a square in one exemplary embodiment. In further exemplary embodiments (not shown), the contour can have other suitable shapes. In this regard, in one exemplary embodiment of a photosensor, a multiplicity of thermodiode element are arranged like honeycombs, for example. In accordance with one preferred exemplary embodiment, the central contact 214 is always at the same distance from the transition between the doping zone 110 and the side doping zone 108. A circle is thus one preferred embodiment.

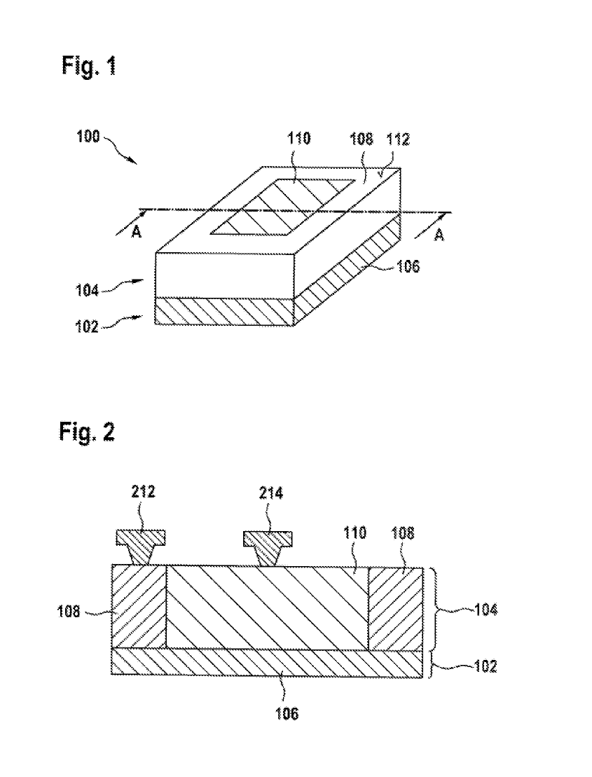

FIG. 2 shows a sectional view of a thermodiode element 100 in accordance with one exemplary embodiment of the present disclosure. The thermodiode element 100 can be one exemplary embodiment of a thermodiode element 100 shown in FIG. 1. In this case, the illustration can correspond to a sectional view along the sectional plane A-A shown in FIG. 1. FIG. 2 shows a cross section through the thermodiode element 100. The thermodiode element 100 comprises a base doping zone 106, a further doping zone 110 and a side doping zone 108. In the illustration in FIG. 2, the side doping zone 108 is arranged on the right and left of the further doping zone 110. The base doping zone 106 is arranged adjacently below the further doping zone 110. The base doping zone 106 forms a first layer 102. The side doping zone 108 and the further doping zone 110 form a second layer 104. The first layer 102 is a monocrystalline layer. The second layer 104 is a further monocrystalline layer.

In the exemplary embodiment shown in FIG. 2, the thermodiode element 100 comprises two contacts 212, 214. A first contact 212 of the two contacts 212, 214 is connected to the side doping zone 108 and arranged at a surface of the side doping zone 108. A second contact 214 of the two contacts 212, 214 is connected to the further doping zone 110 and arranged at a surface of the further doping zone 110. The opposite sides of the doping zones 108, 110 relative to the contacts 212, 214 are in contact with the base doping zone 106.

The base doping zone and the side doping zone have a first doping type. The further doping zone has a second doping type, wherein the second doping type differs from the first doping type. The two doping types are a p-type doping and an n-type doping.

In the exemplary embodiment illustrated in FIG. 2, a layer thickness of the second layer 104 is more than three times a layer thickness of the first layer 102. In this case, the first layer 102 and the second layer 104 together have a layer thickness of less than 4 μm in one exemplary embodiment.

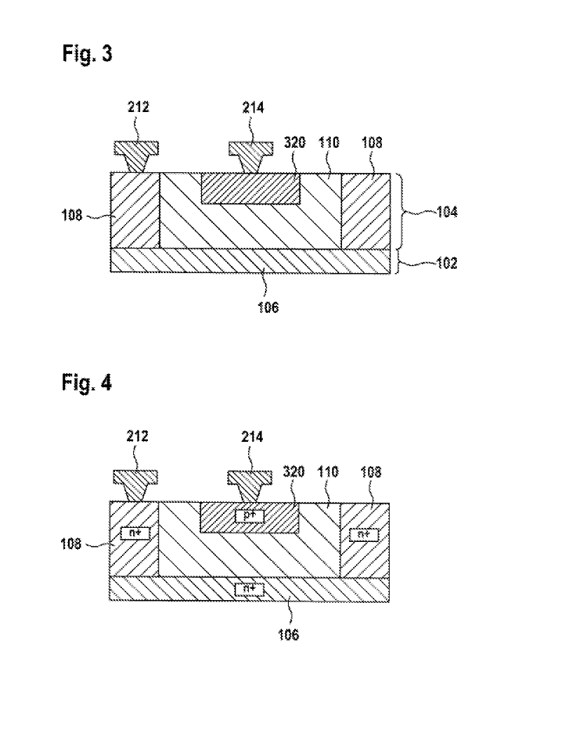

FIG. 3 shows a sectional view of a thermodiode element 100 in accordance with one exemplary embodiment of the present disclosure. The thermodiode element 100 can be one exemplary embodiment of the thermodiode element 100 shown in FIG. 1. A thermodiode element 100 can be understood to be a silicon island 100. In this case, the illustration can correspond to a sectional view along the sectional plane A-A from FIG. 1 and thus to a cross section through the thermodiode element 100. The illustration in FIG. 3 largely corresponds to the illustration in FIG. 2, with the difference that a contact doping zone 320 is arranged within the further doping zone 110. The contact doping zone 320 is encompassed by the further doping zone 110 at three sides, on the left, at the bottom and on the right in the illustration in FIG. 3. In this regard, the contact doping zone 320 forms a contact area for the second contact 214. The second contact 214 can be designated as an external contact 214. In this regard, the contact doping zone 320 provides a contacting area for an external contact 214. The second contact 214 is in contact with the contact doping zone 320.

In the exemplary embodiment shown in FIG. 3, the contact doping zone 320 has the second doping type. In this regard, the contact doping zone 320 has the same doping type as the further doping zone 110. The base doping zone 106 and the side doping zone 108 have a first doping type.

In the exemplary embodiment shown in FIG. 3, the contact doping zone 320 is arranged at a constant distance from the side doping zone 108 at the surface, that is to say at the side facing away from the base doping zone 106 in a tolerance range.

The thermodiode element 100 illustrated in FIG. 3 consists of an exposed silicon island having at least two lead connections and at least three doping zones, wherein in each case at least one n-type doping and one p-type doping are contained. The silicon island comprises at least the first layer 102 and the second layer 104 or, from a different standpoint, the base doping zone 106, the side doping zone 108 and also the further doping zone 110. The side doping zone 108 can be designated as a first doping zone 108, the base doping zone 106 can be designated as a second doping zone 106 and the further doping zone 110 can also be designated as a third doping zone 110. The optional contact doping zone 320 can be designated as a fourth doping zone. The silicon island is delimited toward five spatial directions by a laterally circumferential side doping zone 108 and a second, downwardly delimiting base doping zone 106 of the same doping type (that is to say n or p), which are connected to one another and form a well. In one preferred exemplary embodiment, the two doping zones 106, 108 are highly doped (>10¹⁸ doping atoms/cm³).

The silicon island contains a further doping zone 110 of the opposite doping type within the well formed from the side doping zone 108 and the base doping zone 106. In this case, in one preferred exemplary embodiment, the further doping zone 110 is more lightly doped (>10¹⁵ defects/cm³ but <10¹⁸ defects/cm³) than the base doping zone 106 and the side doping zone 108.

In a further exemplary embodiment, the silicon island 100 furthermore optionally comprises centrally a contact doping zone 320 having the same doping type as the further doping zone 110, but having a higher doping (>10¹⁸ defects/cm³), wherein the contact doping zone 320 is preferably at a constant distance from the circumferential side doping zone 108 at a top delimiting surface.

Depending on the exemplary embodiment, the thermodiode element 100 is contacted via the circumferential side doping zone 108 and the further doping zone 110 or the contact doping zone 320.

The exemplary embodiment of a thermodiode element 100 as illustrated in FIG. 3 advantageously satisfies the requirements made of a low-noise and temperature-sensitive diode for thermographic applications. Firstly, the thermodiode element 100 has no uncovered pn junctions at the surface of the exposed silicon island and furthermore has a low operating point and a low current density. These requirements are satisfied by a doping well, consisting of the base doping zone 106 and the side doping zone 108. This results in a pn junction situated in the depth and, resulting therefrom, a current flow in the defect-poor silicon island instead of at the defect-rich surface. This considerably reduces the noise level and increases the thermal sensitivity on account of the lower current density. In order to make the current flow homogeneous and to realize an ohmic contact, the well doping has been chosen to be highly doped in the exemplary embodiment shown in FIG. 3 (>10¹⁸ defects/cm³). The exact position of the pn junction can be set by means of the doping of the further doping zone 110, which is typically of the order of magnitude of between 10¹⁵ defects/cm³ and 10¹⁸ defects/cm³. The second ohmic contact can be realized either by means of the further doping zone 110 or by means of a more highly doped contact doping zone 320. A suitably high doping can ensure that an ohmic contact is produced instead of a Schottky contact. Both the optional contact doping zone 320 and the associated metal contact are positioned centrally with respect to the circumferential lateral side doping zone 108 in order to ensure a homogeneous current flow through the island volume.

FIG. 4 shows a sectional view of a thermodiode element 100 in accordance with one exemplary embodiment of the present disclosure. In this case, the illustration can correspond to a sectional view along the sectional plane A-A corresponding to FIG. 1 or to a cross section through the thermodiode element 100. The illustration in FIG. 4 largely corresponds to the illustration in FIG. 3, with the difference that corresponding doping designations or corresponding degrees of doping have been entered. The base doping zone 106 and the side doping zone 108 have a high n-type doping (n+) in accordance with this exemplary embodiment. The further doping zone 110 has a normal p-type doping (p). The contact doping zone 320 has a high p-type doping (p+). In this case, the first contact 212 is designated as the cathode and the second contact 214 as the anode.

In one exemplary embodiment, the base doping zone 106 and the side doping zone 108 have a first degree of doping n+. In this regard, the base doping zone 106 and the side doping zone 108 are doped with more than 10¹⁸ defects/cm³ in one exemplary embodiment. In one preferred exemplary embodiment, the base doping zone 106 and the side doping zone 108 have the same degree of doping in a narrow tolerance range of less than 5%.

The further doping zone 110 has a second degree of doping p, and the contact doping zone 320 has a third degree of doping p+. In this case, in one preferred exemplary embodiment, the third degree of doping is greater than the second degree of doping. Preferably, the second degree of doping of the further doping zone 110 is in a range of between 10¹⁵ defects/cm³ and 10¹⁸ defects/cm³.

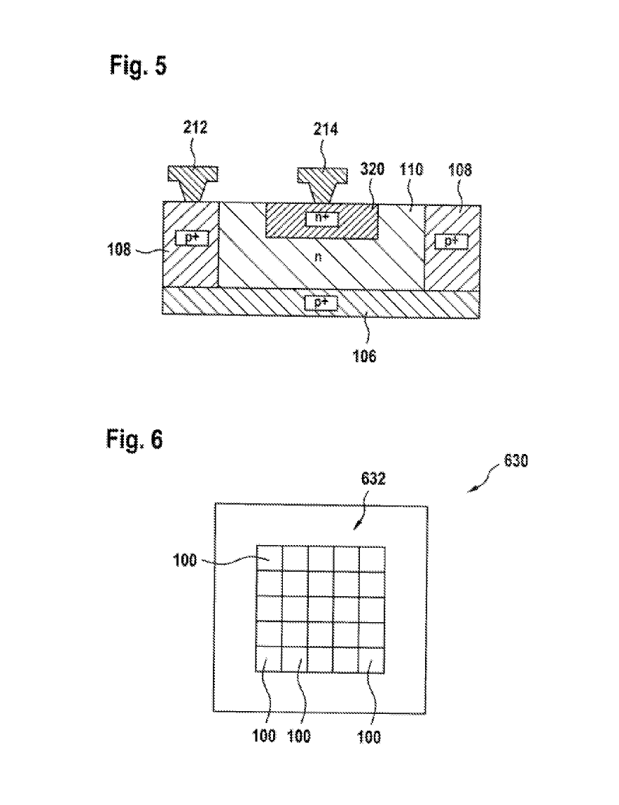

FIG. 5 shows a sectional view of a thermodiode element in accordance with one exemplary embodiment of the present disclosure. In this case, the illustration can correspond to a sectional view along the sectional plane A-A corresponding to FIG. 1 or to a cross section through a thermodiode element 100. The illustration in FIG. 5 largely corresponds to the illustration in FIG. 4, with the difference that the corresponding dopings are inverted. The base doping zone 106 and the side doping zone 108 have a high p-type doping (p+). The further doping zone 110 has a normal n-type doping (n). The contact doping zone 320 has a high n-type doping (n+). In this case, the first contact 212 is designated as the anode and the second contact 214 as the cathode.

Analogously to the description in FIG. 4 it holds true that, in one exemplary embodiment, the base doping zone 106 and the side doping zone 108 have a first degree of doping n+. In this regard, the base doping zone 106 and the side doping zone 108 are doped with more than 10¹⁸ defects/cm³ in one exemplary embodiment. In one preferred exemplary embodiment, the base doping zone 106 and the side doping zone 108 have the same degree of doping in a narrow tolerance range of less than 5%. The further doping zone 110 has a second degree of doping n, and the contact doping zone 320 has a third degree of doping n+. In this case, in one preferred exemplary embodiment, the third degree of doping is greater than the second degree of doping. Preferably, the second degree of doping of the further doping zone 110 is in a range of between 10¹⁵ defects/cm³ and 10¹⁸ defects/cm³. The third degree of doping can correspond to the first degree of doping in terms of absolute value.

FIG. 6 shows a schematic illustration of a thermocamera 630 comprising a photosensor 632 in accordance with one exemplary embodiment of the present disclosure. The photosensor 632 comprises a plurality of thermodiode elements 100. The thermodiode elements 100 can be exemplary embodiments of a thermodiode element 100 shown in the previous figures. In the exemplary embodiment shown, the thermodiode elements 100 are arranged in rows and columns in the photosensor 632. In this case, the illustration in FIG. 6 shows five rows and five columns by way of example. For the sake of clarity, only four thermodiode elements 100 are provided with reference signs here.

Further elements of the thermocamera 630 are not illustrated in FIG. 6. In this regard, the thermocamera 630 comprises at least one optical system (not illustrated) and an evaluation device (not illustrated) and a communication interface.

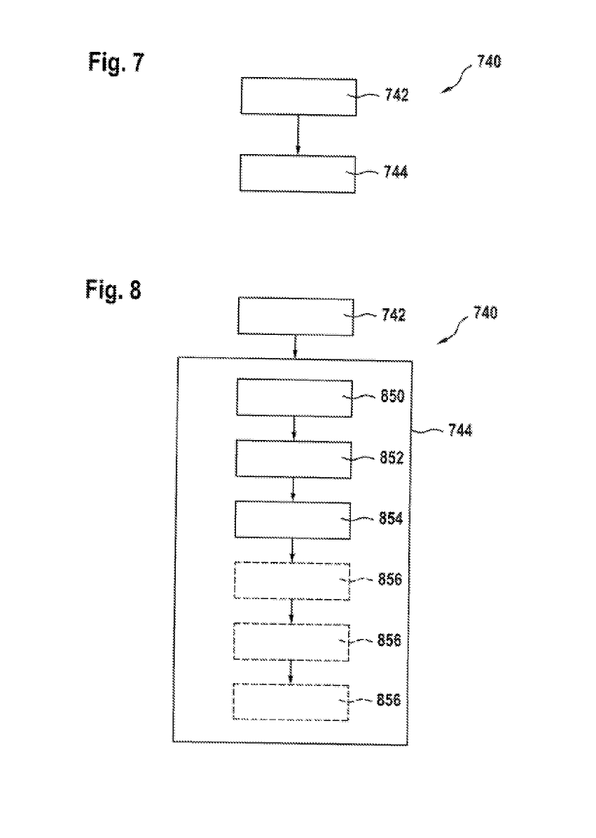

FIG. 7 shows a flow chart of a method 740 for producing a thermodiode element for a photosensor in accordance with one exemplary embodiment of the present disclosure. The thermodiode element can be one exemplary embodiment of a thermodiode element 100 described in the previous figures. The method 740 comprises a step 742 of providing a semiconductor substrate and a step 744 of forming a base doping zone, a side doping zone and a further doping zone. In this case, step 744 of forming makes use of a method of semiconductor technology in order to produce a variant of a thermodiode element as described on the basis of exemplary embodiments in the previous figures.

FIG. 8 shows a flow chart of a method 740 for producing a thermodiode element in accordance with one exemplary embodiment of the present disclosure. The thermodiode element can be one exemplary embodiment of a thermodiode element 100 described in the previous figures. The method 740 is one exemplary embodiment of the method 740 for producing a thermodiode element for a photosensor for a thermocamera for infrared radiation measurement as shown in FIG. 7. In step 744 of forming, as described in FIG. 7, a plurality of substeps 850, 852, 854, 856, 858, 860 are illustrated in FIG. 8.

A first substep 850 of creating involves creating a first monocrystalline layer on a semiconductor substrate having a base doping zone of a first doping type. A second substep 852 of depositing, which follows the first substep 850 of creating, involves depositing a second monocrystalline layer on the first layer having a further doping zone of a second doping type, which is opposite to the first doping type. A third substep 854 of introducing, which follows the second substep 852 of depositing, involves introducing a dopant of the first doping type and driving it in until the side doping zone is connected to the base doping zone.

In one exemplary embodiment, the method 740 comprises an optional further substep 856 of introducing after substep 854 of introducing, wherein the further substep 856 of introducing involves introducing a contact doping zone of the second doping type centrally in respect to the side doping zone.

In one exemplary embodiment, the method 740 comprises a substep 858 of contacting the side doping zone by means of a first contact and contacting the further doping zone or alternatively the contact doping zone by means of a second contact. Depending on the exemplary embodiment, the first contact and the second contact are formed as contact pad, line or metallic leads.

In one exemplary embodiment, the method 740 comprises an optional step 860 of exposing, for example of etching. Step 860 of exposing involves exposing a silicon island, wherein the silicon island comprises at least the base doping zone, the side doping zone and the further doping zone. If the thermodiode element comprises a contact doping zone or the optional substep 856 was carried out, then the silicon island also comprises the contact doping zone.

The method 740 for producing a thermodiode element as illustrated in FIG. 8 is described by way of example below on the basis of an exemplary embodiment. Step 850 of creating involves providing a first monocrystalline layer having a second doping of a first doping type on a substrate. The first monocrystalline layer provides the base doping zone. Step 852 of depositing involves depositing a second monocrystalline layer having a third doping of a second doping type on the first layer. Step 854 of introducing involves introducing a dopant of the first doping type and driving in the dopant until the first doping zone, that is to say the side doping zone, is connected to the second doping zone, that is to say the base doping zone. The base doping zone and the side doping zone together form a well. Step 854 of introducing involves introducing the dopant in the edge regions of the second monocrystalline layer, wherein a region arranged centrally in the second monocrystalline layer is not processed in step 854 of introducing. This centrally arranged region that is not processed in step 854 of introducing forms the further doping zone.

In one exemplary embodiment, a fourth doping of the second doping type is optionally introduced centrally with respect to the further doping zone in an optional further step 856 of introducing. The contact doping zone is produced in the further step 856 of introducing. In this case, doping is carried out proceeding from a surface or a side of the further doping zone that faces away from the base doping zone, wherein the further doping zone remains between the contact doping zone and the base doping zone and between the contact doping zone and the side doping zone.

In one exemplary embodiment, optionally step 858 of contacting involves contacting the side doping zone and the further doping zone or the contact doping zone by means of metallic leads.

In one exemplary embodiment, optionally step 860 of etching involves exposing the silicon island, that is to say the thermodiode element, by means of at least one etching step.

The method 740 described advantageously provides a low-noise diode design having a low operating point and a high temperature sensitivity.

The dopings and the growth of the individual layers are realized by means of standard semiconductor processes. In this case, the second monocrystalline layer is grown epitaxially for example with the third doping. The total layer thickness of the first and second layers is less than 4 μm. It results from the fact that, firstly, the base doping zone and the side doping zone are connected by diffusion and, secondly, the heat capacity of the silicon island does not become excessively high, in order to be able to achieve a high image refresh rate. The process temperatures that occur in this case already provide for a first diffusion of the base doping zone in the first layer into the second layer. The circumferential side doping zone is subsequently introduced with relatively high doses (>10¹⁵ cm⁻²) and acceleration voltages (>200 kV) perpendicularly by means of ion implantation. The subsequent thermal step for annealing the damage on account of the implantation and for outdiffusion of the dopant is chosen in such a way that a connection of the first doping and the second doping arises (>1000° C.). The optional fourth doping for providing the contact doping zone is carried out with a dose having a similar magnitude to that of the first doping, although with lower acceleration voltages (>20 kV; but <50 kV) and a lower drive-in temperature of <1000° C.).

What is claimed is:

1. A thermodiode element for a photosensor of a thermocamera that is usable for infrared radiation measurement, the thermodiode element comprising:
a semiconductor substrate that includes:
a first layer that has a base doping zone with a first doping type;
a second layer that adjoins the first layer and that has:
a side doping zone with the first doping type; and
a further doping zone that is arranged as an island in the side doping zone, and that has a second doping type opposite to the first doping type;
wherein the base doping zone is arranged so as to adjoin the further doping zone.

2. The thermodiode according to claim 1, wherein at least one of the base doping zone and the side doping zone has a high doping.

3. The thermodiode according to claim 1, wherein the further doping zone has a medium doping.

4. The thermodiode according to claim 1, further comprising a contact doping zone that is embedded within the further doping zone, that has the second doping type, and that is configured as a contacting area for an external contact.

5. The thermodiode according to claim 4, wherein the contact doping zone has a high doping.

6. The thermodiode according to claim 1, further comprising:
a first contact positioned at the side doping zone; and
a second contact positioned at the further doping zone or at a contact doping zone that is embedded within the further doping zone and that has the second doping type.

7. The thermodiode according to claim 1, wherein the first layer and the second layer together have a layer thickness of four micrometers or less.

8. A photosensor for a thermocamera usable for infrared radiation measurement, comprising:
an array that includes a plurality of thermodiode elements, each of the plurality of thermodiode elements having:
a semiconductor substrate that includes:
a first layer that has a base doping zone with a first doping type;
a second layer that adjoins the first layer and that has:
a side doping zone with the first doping type; and
a further doping zone that is arranged as an island in the side doping zone,
and that has a second doping type opposite to the first doping type;
wherein the base doping zone is arranged so as to adjoin the further doping zone.

9. A method of producing a thermodiode element for a photosensor of a thermocamera usable for infrared radiation measurement, comprising:
forming a layer construction on a semiconductor substrate that includes a first layer and a second layer; and
forming, via semiconductor technology:
a base doping zone with a first doping type in the first layer;
a side doping zone with the first doping type in the second layer; and
a further doping zone, with a second doping type opposite the first doping type, in the second layer as an island in the side doping zone;
wherein the base doping zone is formed so as to adjoin the further doping zone.

10. The method according to claim 9, wherein:
forming the layer construction includes:
creating the first layer as a monocrystalline layer on the semiconductor substrate; and
applying the second layer as a monocrystalline layer on the first layer; and
forming the side doping zone includes introducing dopant of the first doping type into a region of the second layer which surrounds the further doping zone.

11. The method according to claim 10, further comprising:
introducing a dopant of the second doping type into the further doping zone to form a contact doping zone.

12. The method according to claim 9, further comprising:
positioning a first contact at the side doping zone; and
either:
(i) positioning a second contact at the further doping zone, or
(ii) introducing a dopant of the second doping type into the further doping zone to form a contact doping zone, and positioning the second contact at the contact doping zone.

13. The method according to claim 9, further comprising:
exposing at least the base doping zone, the side doping zone, and the further doping zone of the thermodiode element.
